(19) United States
(12) Patent Application Publication
(10) Pub. No.: US 2025/0354264 A1
(43) Pub. Date: Nov. 20, 2025

(54) DEPOSITION APPARATUS AND METHOD OF DRIVING THE SAME

(71) Applicant: SAMSUNG DISPLAY CO., LTD., Yongin-si (KR)

(72) Inventors: Choel Min JANG, Yongin-si (KR); Myung Soo HUH, Yongin-si (KR); Min Gyu PARK, Yongin-si (KR); Hee Yong LEE, Yongin-si (KR)

(21) Appl. No.: 18/980,665

(22) Filed: Dec. 13, 2024

(30) Foreign Application Priority Data
May 16, 2024 (KR) 10-2024-0063760

(51) Int. Cl. C23C 16/458; C23C 16/50; H10K 71/16

(52) U.S. Cl. CPC C23C 16/4583; C23C 16/50; H10K 71/164

(57) ABSTRACT

A deposition apparatus and a method of driving the same are disclosed. A deposition apparatus includes a processor chamber configured to deposit a deposition material on a substrate, and a transfer chamber configured to transport the substrate to the processor chamber. In a partial region of the processor chamber, the processor chamber and the transfer chamber overlap with each other.

### CROSS-REFERENCE TO RELATED APPLICATION

The present application claims priority to and the benefit of Korean Patent Application No. 10-2024-0063760; filed on May 16, 2024 in the Korean Intellectual Property Office, the entire disclosure of which is incorporated herein by reference.

### BACKGROUND

### 1. Field

Aspects of embodiments of the present disclosure relate to a deposition apparatus and a method of driving the same.

### 2. Description of the Related Art

An OLED light emitting element is a self-luminous element which autonomously emits light, using an electroluminescent phenomenon in which light is emitted when a current flows in a fluorescent organic compound. In the OLED light emitting element, a hole injection layer, a light emitting layer, and the like, as the other component layers except anode and cathode electrodes, are formed of an organic thin film, and the organic thin film is deposited on a substrate, using a vacuum thermal deposition method.

A cluster type deposition apparatus is used as an apparatus to which the above-described deposition method is applied. In the cluster type deposition apparatus, a transfer chamber for transporting a substrate is disposed at a central portion, and a plurality of processor chambers are connected to the transfer chamber at a periphery of the transfer chamber to form one cluster module.

The above information disclosed in this Related Art section is provided for enhancement of understanding of the background of the disclosure and, therefore, it may contain information that does not form the prior art that is already known in this country to a person of ordinary skill in the art.

### SUMMARY

According to an aspect of embodiments of the present disclosure, a deposition apparatus and a method of driving the same are provided, in which a length of a chamber is decreased, such that efficiency can be improved in terms of space.

According to one or more embodiments of the present disclosure, a deposition apparatus includes: a processor chamber configured to deposit a deposition material on a substrate; and a transfer chamber configured to transport the substrate to the processor chamber, wherein, in a partial region of the processor chamber, the processor chamber and the transfer chamber overlap with each other.

The processor chamber may include: a third appearance member defining an internal space therein; a nozzle portion configured to supply the deposition material to the internal space; a substrate holder located in the internal space, the substrate holder configured to have the substrate placed thereon; and a first buffer module and a second buffer module coupled to opposite ends of the substrate holder.

The third appearance member may include a first region and a second region. The first region may correspond to the partial region of the processor chamber. The substrate holder may be movable in the second region. The first buffer module may be movable in the first region and the second region.

The transfer chamber may include: a transport robot configured to allow the substrate to be placed on the substrate holder; a gate configured to provide a path through which the transport robot is movable to the internal space; and a gate valve configured to define an open state or a closed state of the gate.

The gate valve may be disposed on a top of the gate.

In the partial region, the processor chamber may be located under the transfer chamber.

In the closed state of the gate, the internal space may maintain a vacuum state.

The third appearance member may include a first region, a second region, and a third region, and the second region may be located between the first region and the third region. The partial region may correspond to the first region. The third region of the third appearance member may be attachable and detachable.

The third appearance member may include a first region, a second region, and a third region, and the second region may be located between the first region and the third region. The partial region may correspond to the first region. In the first and third regions, a first width of the third appearance member in a first direction may have a first length. In the second region, a second width of the third appearance member in the first direction may have a second length greater than the first length.

According to one or more embodiments of the present disclosure, a method of driving a deposition apparatus includes a processor chamber including a substrate holder and a transfer chamber configured to transport a substrate on the substrate holder includes: placing the substrate on the substrate holder; forming a vacuum state in an internal space of the processor chamber; and depositing a deposition material on the substrate while the substrate holder reciprocates, wherein, in a partial region of the processor chamber, the processor chamber and the transfer chamber overlap with each other.

The processor chamber may further include: a third appearance member defining an internal space therein; a nozzle portion configured to supply the deposition material to the internal space; and a first buffer module and a second buffer module coupled to opposite ends of the substrate holder.

The third appearance member may include a first region and a second region. The first region may correspond to the partial region of the processor chamber. The substrate holder may be movable in the second region. The first buffer module may be movable in the first region and the second region.

The transfer chamber may include: a transport robot configured to allow the substrate to be placed on the substrate holder; a gate configured to provide a path through which the transport robot is movable to the internal space; and a gate valve configured to define an open state or a closed state of the gate.

The gate valve may be disposed on a top of the gate.

In the partial region, the processor chamber may be located under the transfer chamber.

The forming of the vacuum state in the internal space may include allowing, by the gate valve, the gate to be in the closed state.

The third appearance member may include a first region, a second region, and a third region, and the second region may be located between the first region and the third region. The partial region may correspond to the first region. The third region of the third appearance member may be attachable and detachable.

The third appearance member may include a first region, a second region, and a third region, and the second region may be located between the first region and the third region. The partial region may correspond to the first region. In the first and third regions, a first width of the third appearance member in a first direction may have a first length. In the second region, a second width of the third appearance member in the first direction may have a second length greater than the first length.

The depositing of the deposition material on the substrate may include allowing the nozzle portion to overlap with the first buffer module and arranging the second buffer module on the third region.

The depositing of the deposition material on the substrate may include allowing the nozzle portion to overlap with the second buffer module and arranging the first buffer module on the first region.

### BRIEF DESCRIPTION OF THE DRAWINGS

Some example embodiments will be described more fully herein with reference to the accompanying drawings; however, the present disclosure may be embodied in different forms and should not be construed as limited to the embodiments set forth herein. Rather, these embodiments are provided so that this disclosure will be thorough and complete, and will fully convey the scope of the present disclosure to those skilled in the art.

In the drawing figures, dimensions may be exaggerated for clarity of illustration. It is to be understood that when an element is referred to as being “between” two elements, it may be the only element between the two elements, or one or more intervening elements may also be present. Like reference numerals refer to like elements throughout.

FIG. 1 is a view illustrating a deposition apparatus in accordance with one or more embodiments of the present disclosure.

FIG. 2 is an enlarged view of a region “X” of the deposition apparatus shown in FIG. 1.

FIG. 3 is a perspective view illustrating a gate valve and a gate, which are shown in FIG. 2.

FIG. 4 is a view illustrating a third appearance member shown in FIG. 2.

FIG. 5 is a flowchart illustrating a method of driving the deposition apparatus shown in FIG. 1.

FIG. 6 is a view illustrating a step S100 shown in FIG. 5.

FIG. 7 is a view illustrating a step S200 shown in FIG. 5.

FIGS. 8 to 11 are views illustrating a step S300 shown in FIG. 5.

### DETAILED DESCRIPTION

Herein, some embodiments of the present disclosure will be described in further detail with reference to the accompanying drawings. In the description below, only a necessary part to understand an operation according to the present disclosure may be described and descriptions of other parts may be omitted in order not to unnecessarily obscure subject matter of the present disclosure. In addition, the present disclosure is not limited to the example embodiments described herein, but may be embodied in various different forms. Rather, example embodiments described herein are provided to thoroughly and completely describe the disclosed content and to sufficiently transfer the ideas of the disclosure to a person of ordinary skill in the art.

In the entire specification, when an element is referred to as being “connected” or “coupled” to another element, it may be directly connected or coupled to the another element or be indirectly connected or coupled to the another element with one or more intervening elements interposed therebetween. The technical terms used herein are used for the purpose of illustrating a specific embodiment but are not intended to limit the embodiment. It is to be understood that when a component “includes” an element, unless there is another opposite description thereof, it is to be understood that the component does not exclude another element but may further include another element. It is to be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It is to be understood that, although the terms “first,” “second,” etc. may be used herein to describe various elements, these elements are not to be limited by these terms. These terms are used to distinguish one element from another element. Thus, a “first” element discussed below could also be termed a “second” element without departing from the teachings of the present disclosure.

Spatially relative terms, such as “below,” “above,” and the like, may be used herein for ease of description to describe the relationship of one element to another element, as illustrated in the figures. It is to be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the example term, “above,” may encompass both an orientation of above and below. The apparatus may be otherwise oriented (e.g., rotated 90 degrees or at other orientations) and the spatially relative descriptors used herein interpreted accordingly.

In addition, the embodiments of the disclosure may be described here with reference to schematic diagrams of ideal embodiments (and an intermediate structure) of the present disclosure, such that changes in a shape as shown due to, for example, manufacturing technology and/or a tolerance may be expected. Therefore, the embodiments of the present disclosure are not to be limited to the specific shapes of a region shown here, but include shape deviations caused by, for example, the manufacturing technology. The regions shown in the drawings are schematic in nature, and the shapes thereof do not necessarily represent the actual shapes of the regions of the device, and do not limit the scope of the disclosure.

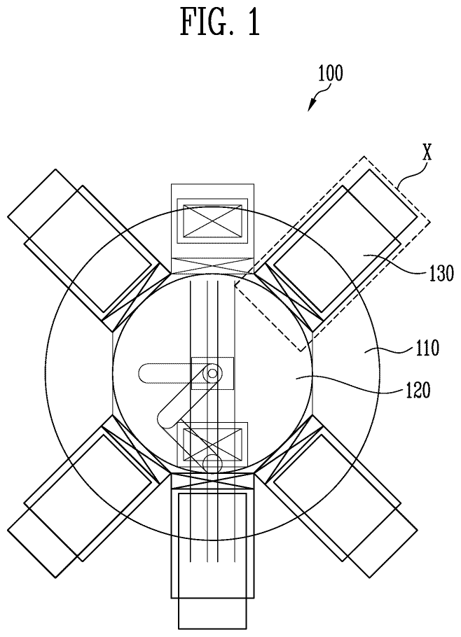

FIG. 1 is a view illustrating a deposition apparatus in accordance with one or more embodiments of the present disclosure. FIG. 1 is a view illustrating a deposition apparatus 100 viewed from the top.

Referring to FIG. 1, the deposition apparatus 100 may include a first appearance member 110, a transfer chamber 120, and a processor chamber 130.

The first appearance member 110, the transfer chamber 120, and the processor chamber 130 may have a three-dimensional shape.

The first appearance member 110 may be disposed on a ground, and support the transfer chamber 120 and the processor chamber 130, which are disposed on the first appearance member 110.

The transfer chamber 120 may be disposed on the first appearance member 110. For example, the transfer chamber 120 may be disposed on a central portion of the first appearance member 110. The transfer chamber 120 may transport a substrate to the processor chamber 130.

In an embodiment, a plurality of processor chambers 130 may be connected to the transfer chamber 120 at a periphery of the transfer chamber 120 to form a cluster module. In FIG. 1, it is illustrated that four processor chambers 130 are connected to the transfer chamber 120. However, embodiments of the present disclosure are not limited thereto. Various numbers of processor chambers 130 may be connected to the transfer chamber 120.

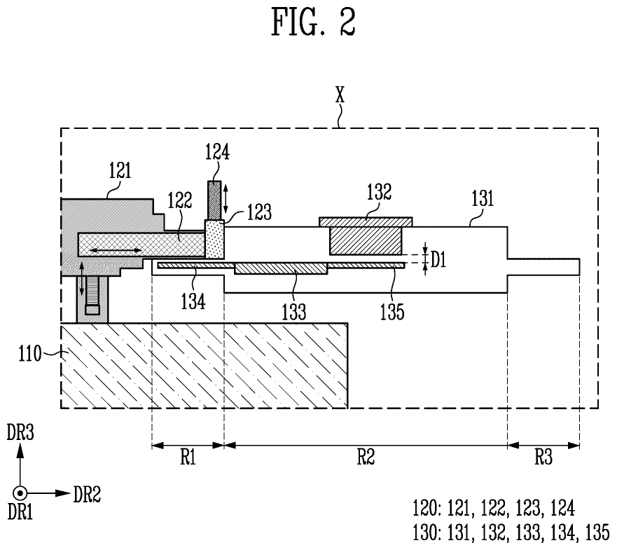

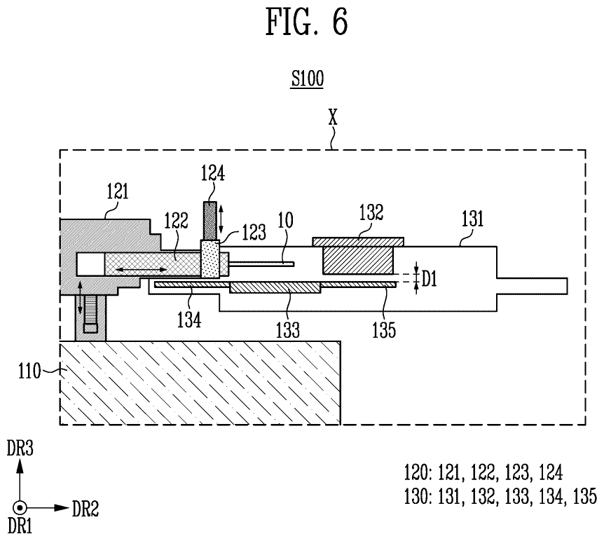

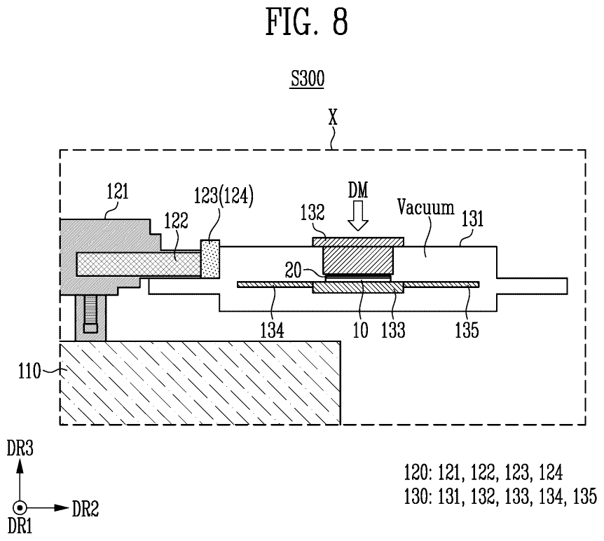

The processor chamber 130 may deposit a deposition material DM (see FIG. 8) on a substrate 10 (see FIG. 6). The transfer chamber 120 and the processor chamber 130 will be described in further detail later with reference to FIG. 2.

FIG. 2 is an enlarged view of a region “X” of the deposition apparatus shown in FIG. 1.

Referring to FIGS. 1 and 2, the deposition apparatus 100 may include the first appearance member 110, the transfer chamber 120, and the processor chamber 130.

The transfer chamber 120 may include a second appearance member 121, a transport robot 122, a gate 123, and a gate valve 124.

The second appearance member 121 may be disposed on the first appearance member 110. The second appearance member 121 may support the transport robot 122, the gate 123, and the gate valve 124.

The transport robot 122 may be coupled to the second appearance member 121. The transport robot 122 may be moved in a second direction DR2 and a third direction DR3. Based on this movement, the transport robot 122 may perform an operation of holding a substrate on a substrate holder 133.

The second appearance member 121 and a third appearance member 131 may be connected to each other with the gate 123 interposed therebetween. In addition, the gate 123 may be in an open state or a closed state. When the gate 123 is in the open state, the gate 123 may provide a path through which the transport robot is movable to an internal space of the third appearance member 131.

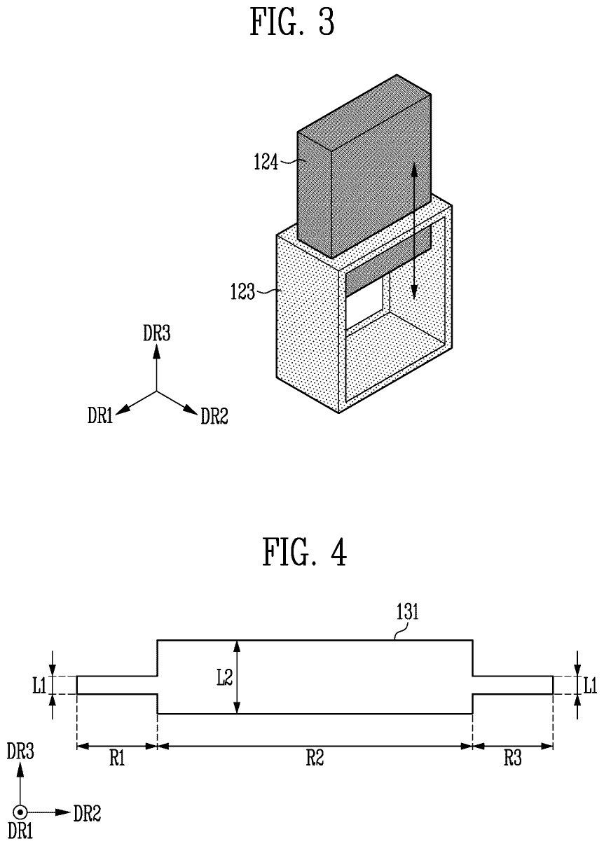

The gate valve 124 may be disposed on a top of the gate 123. The gate valve 124 may determine, or define, the open state or the closed state of the gate 123. When the gate valve 124 moves in an opposite direction of the third direction DR3, the gate 123 may be in the closed state. By contrast, when the gate valve 124 moves in the third direction DR3, the gate 123 may be in the open state. This will be described in further detail later with reference to FIG. 3.

The processor chamber 130 may include the third appearance member 131, a nozzle portion 132, the substrate holder 133, a first buffer module 134, and a second buffer module 135.

The third appearance member 131 may define the internal space. The substrate holder 133, the first buffer module 134, and the second buffer module 135 may be disposed in the internal space. The third appearance member 131 may include first to third regions R1 to R3. In the first region R1 of the third appearance member 131, the transfer chamber 120 and the processor chamber 130 may overlap with each other. In the first region R1, the third appearance member 131 may be disposed under the transfer chamber 120.

The nozzle portion 132 may be configured to supply the deposition material DM to the internal space.

The substrate holder 133 may provide a space in which the substrate 10 (see FIG. 3) is to be held thereon. The first buffer module 134 and the second buffer module 135 may be coupled to opposite ends of the substrate holder 133.

In a deposition process, the substrate holder 133, the first buffer module 134, and the second buffer module 135 may reciprocate in the second direction DR2 and an opposite direction of the second direction DR2. The substrate holder 133 may move in the second region R2. The first buffer module 134 may move in the first region R1 and the second region R2. The second buffer module 135 may move in the second region R2 and the third region R3.

In an embodiment, in the deposition process, a vacuum plasma state formed between the nozzle portion 132 and the substrate holder 133 is to be maintained even in a section in which the substrate holder 133 does not overlap with the nozzle portion 132. In the section in which the substrate holder 133 does not overlap with the nozzle portion 132, the first buffer module 134 or the second buffer module 135 may overlap with the nozzle portion 132 instead of the substrate holder 133. In a section in which the first buffer module 134 overlaps with the nozzle portion 132, the first buffer module 134 may be in a state in which the first buffer module 134 is spaced apart from the nozzle portion 132 by a first length D1. In a section in which the second buffer module 135 overlaps with the nozzle portion 132, the second buffer module 135 may be in a state in which the second buffer module 135 is spaced apart from the nozzle portion 132 by the first length D1. Accordingly, a pressure formed under the nozzle portion 132 can be constantly maintained. In addition, the vacuum plasma state formed under the nozzle portion 132 by the corresponding pressure can be constantly maintained even in the section in which the substrate holder 133 does not overlap with the nozzle portion 132.

FIG. 3 is a perspective view illustrating the gate valve and the gate, which are shown in FIG. 2.

Referring to FIGS. 2 and 3, the gate 123 and the gate valve 124 may have a three-dimensional shape extending in a first direction DR1, the second direction DR2, and the third direction DR3. However, in embodiments of the present disclosure, the gate 123 and the gate valve 124 are not limited to the shape shown in FIG. 3, and may have various shapes.

The gate 123 may be penetrated such that an object can pass through the gate 123 from a first surface to an opposite surface facing the first surface thereof.

The gate valve 124 may operate in the third direction DR3 or the opposite direction of the third direction DR3.

When the gate 123 is in the closed state, the gate valve 124 may move in the opposite direction of the third direction DR3, to be in a state in which the gate valve 124 blocks between the first surface and the opposite surface of the gate 123. When the gate 123 is in the closed state, the transport robot 122 may not pass through the gate 123.

By contrast, when the gate 123 is in the open state, the gate valve 124 may move in the third direction DR3, to be in a state in which the gate 123 is penetrated between the first surface and the opposite surface of the gate 123. When the gate 123 is in the open state, the transport robot 122 may pass through the gate 123.

FIG. 4 is a view illustrating the third appearance member shown in FIG. 2.

Referring to FIGS. 2 and 4, the third appearance member 131 may include the first to third regions R1 to R3.

As shown in FIG. 4, the third appearance member 131 in the first region R1 may protrude from the third appearance member 131 in the second region R2. Similarly, the third appearance member 131 in the third region R3 may protrude from the third appearance member 131 in the second region R2.

In the first region R1, the third appearance member 131 may have a first width L1 in the third direction DR3. Similarly, in the third region R3, the third appearance member 131 may have the first width L1 in the third direction DR3. In addition, when the third appearance member 131 in the first region R1 extends in the second direction, the third appearance member 131 in the first region R1 may meet the third appearance member 131 in the third region R3.

In the second region R2, the third appearance member 131 may have a second width L2 in the third direction DR3. The second width L2 may be greater than the first width L1.

In an embodiment, in the first region R1, the third appearance member 131 has only a width (e.g., a minimum width) with which the first buffer module 134 can move, such that space efficiency of the deposition apparatus 100 can be improved. Similarly, in the third region R3, the third appearance member 131 has only width (e.g., a minimum width) with which the second buffer module 135 can move, such that the space efficiency of the deposition apparatus 100 can be improved.

In some embodiments, the third appearance member 131 in the third region R3 may be attachable and detachable.

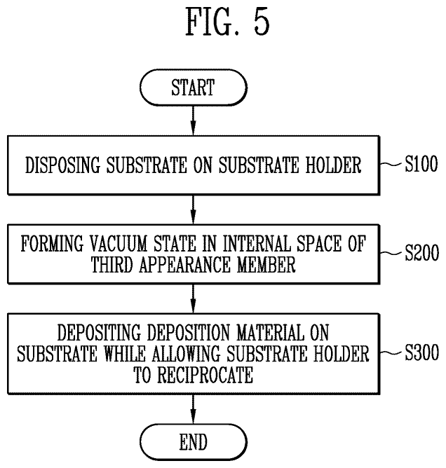

FIG. 5 is a flowchart illustrating a method of driving a deposition apparatus, such as the deposition apparatus shown in FIG. 1.

Referring to FIG. 5, a step, or task, S100 of disposing the substrate 10 on the substrate holder 133 may be performed.

In addition, a step, or task, S200 of forming a vacuum state in the internal space of the third appearance member 131 may be performed.

In addition, a step, or task, S300 of depositing the deposition material DM on the substrate 10 while allowing the substrate holder 133 to reciprocate may be performed.

FIG. 6 is a view illustrating the step S100 shown in FIG. 5.

Referring to FIGS. 1 to 6, when the gate 123 in the open state, the gate 123 may provide a path through which the transport robot 122 is movable to the internal space of the third appearance member 131.

The transport robot 122 may move in the second direction DR2 and the third direction DR3. Based on this movement, the transport robot 122 may dispose the substrate 10 on the substrate holder 133 located in the internal space of the third appearance member 131.

In the step S100, the substrate holder 133 may be located in the second region R2. The first buffer module 134 may be located in the first region R1. The second buffer module 135 may be located in the second region R2 and overlap with the nozzle portion 132.

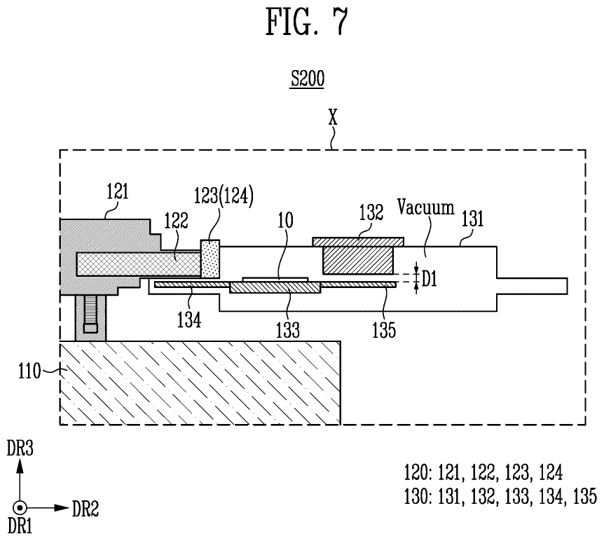

FIG. 7 is a view illustrating the step S200 shown in FIG. 5.

Referring to FIGS. 1 to 7, the gate 123 may be changed from the open state to the closed state. In addition, the internal space of the third appearance member 131 may form a vacuum. In addition, the vacuum plasma state may be formed under the nozzle portion 132, such that deposition of the deposition material DM is prepared. The vacuum is formed in the internal space, such that the deposition can be made with an intended thickness and an intended area without interrupting a straightness of the deposition material DM toward the substrate 10.

In the step S200, the substrate holder 133 may maintain a state in which the substrate holder 133 is located in the second region R2. The first buffer module 134 may maintain a state in which the first buffer module 134 is located in the first region R1. The second buffer module 135 may maintain a state in which the second buffer module 135 is located in the second region R2 and overlaps with the nozzle portion 132.

FIGS. 8 to 11 are views illustrating the step S300 shown in FIG. 5.

Referring to FIG. 8, in the step S300, first, the substrate holder 133 may move in the second direction DR2. Accordingly, the substrate holder 133 may maintain the state in which the substrate holder 133 is located in the second region R2, and overlap with the nozzle portion 132. The first buffer module 134 may be located in the second region R2. The second buffer module 135 may maintain the state in which the second buffer module 135 is located in the second region R2.

The deposition material DM may be supplied to the internal space of the third appearance member 131 through the nozzle portion 132. In addition, the deposition material DM may form a deposition layer 20 on the substrate 10, using the vacuum plasma state formed under the nozzle portion 132.

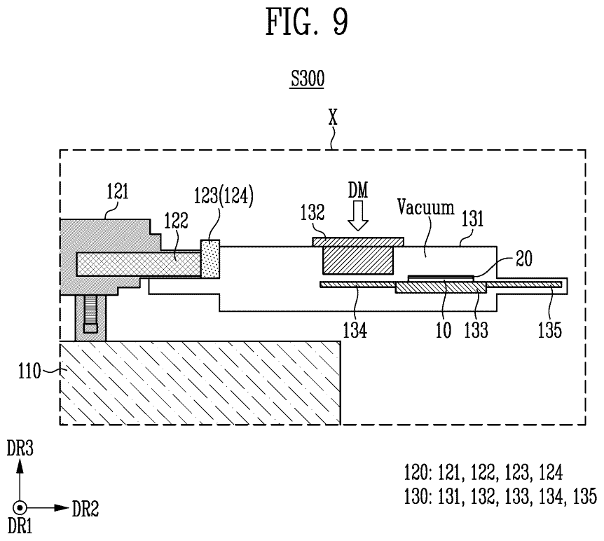

Referring to FIG. 9, next, the substrate holder 133 may move in the second direction DR2. Accordingly, the substrate holder 133 may maintain the state in which the substrate holder 133 is located in the second region R2. The first buffer module 134 may maintain the state in which the first buffer module 134 is located in the second region R2, and overlap with the nozzle portion 132. The second buffer module 135 may be located in the third region R3.

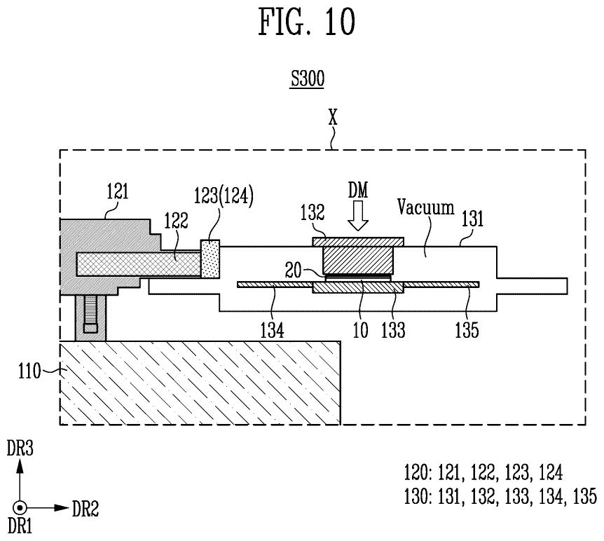

Referring to FIG. 10, next, the substrate holder 133 may move in the opposite direction of the second direction DR2. Accordingly, the substrate holder 133 may maintain the state in which the substrate holder 133 is located in the second region R2, and overlap with the nozzle portion 132. The first buffer module 134 may maintain the state in which the first buffer module 134 is located in the second region R2. The second buffer module 135 may be located in the second region R2.

The deposition material DM may form the deposition layer 20 on the substrate 10, using the vacuum plasma state formed under the nozzle portion 132.

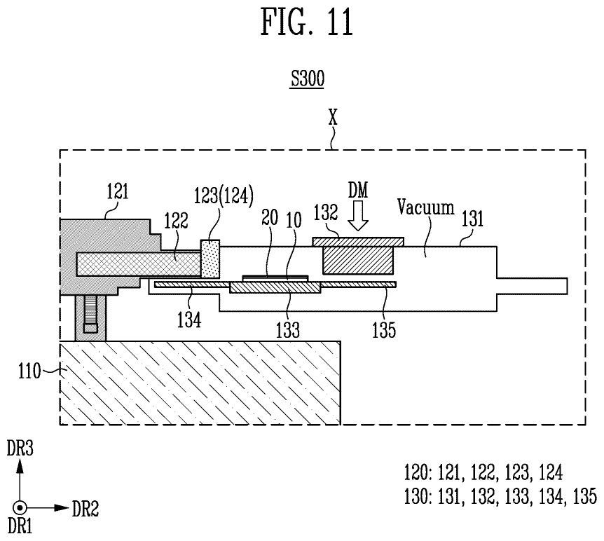

Referring to FIG. 11, next, the substrate holder 133 may move in the opposite direction of the second direction DR2. Accordingly, the substrate holder 133 may maintain the state in which the substrate holder 133 is located in the second region R2. The first buffer module 134 may be located in the first region R1. The second buffer module 135 may maintain the state in which the second buffer module 135 is located in the second region R2, and overlap with the nozzle portion 132. As described with reference to FIGS. 8 to 11, the deposition material DM may be deposited on the substrate 10 while the substrate holder 130 reciprocates.

In the deposition apparatus 100 in accordance with embodiments of the present disclosure, in the first region R1 of the third appearance member 131, the transfer chamber 120 and the processor chamber 130 may overlap with each other. In the first region, the third appearance member 131 may be disposed under the transfer chamber 120. The gate valve 124 may be disposed on the top of the gate 123.

The deposition apparatus 100 in accordance with embodiments of the present disclosure has the above-described structure, such that the area occupied by the processor member 130 in the second direction DR2 can be decreased. Accordingly, the deposition apparatus 100 can improve efficiency in terms of space.

Further, in the first region R1 and the third region R3, the third appearance member 131 has the shape shown in FIG. 2, such that efficiency can be improved in terms of manufacturing cost in addition to in terms of space. In an embodiment, in the third region, the third appearance member 131 is attachable and detachable, such that efficiency can be improved in terms of space.

In accordance with embodiments of the present disclosure, a deposition apparatus and a method of driving the same are provided, in which the length of the chamber is decreased, such that efficiency can be improved in terms of space.

While some example embodiments have been disclosed herein, and although specific terms are employed, these are used and are to be interpreted in a generic and descriptive sense and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it is to be understood by those of skill in the art that various changes in form and details may be made without departing from the spirit and scope of the present disclosure as set forth in the claims.

What is claimed is:

1. A deposition apparatus comprising:
a processor chamber configured to deposit a deposition material on a substrate; and
a transfer chamber configured to transport the substrate to the processor chamber,
wherein, in a partial region of the processor chamber, the processor chamber and the transfer chamber overlap with each other.

2. The deposition apparatus of claim 1, wherein the processor chamber comprises:
a third appearance member defining an internal space therein;
a nozzle portion configured to supply the deposition material to the internal space;
a substrate holder located in the internal space, the substrate holder configured to have the substrate placed thereon; and
a first buffer module and a second buffer module coupled to opposite ends of the substrate holder.

3. The deposition apparatus of claim 2, wherein the third appearance member comprises a first region and a second region,
wherein the first region corresponds to the partial region of the processor chamber,
wherein the substrate holder is movable in the second region, and
wherein the first buffer module is movable in the first region and the second region.

4. The deposition apparatus of claim 2, wherein the transfer chamber comprises:
a transport robot configured to allow the substrate to be placed on the substrate holder;
a gate configured to provide a path through which the transport robot is movable to the internal space; and
a gate valve configured to define an open state or a closed state of the gate.

5. The deposition apparatus of claim 4, wherein the gate valve is on a top of the gate.

6. The deposition apparatus of claim 5, wherein, in the partial region, the processor chamber is located under the transfer chamber.

7. The deposition apparatus of claim 4, wherein, in the closed state of the gate, the internal space maintains a vacuum state.

8. The deposition apparatus of claim 2, wherein the third appearance member comprises a first region, a second region, and a third region, and the second region is located between the first region and the third region,
wherein the partial region corresponds to the first region, and
wherein the third region of the third appearance member is attachable and detachable.

9. The deposition apparatus of claim 2, wherein the third appearance member comprises a first region, a second region, and a third region, and the second region is located between the first region and the third region,
wherein the partial region corresponds to the first region,
wherein, in the first and third regions, a first width of the third appearance member in a first direction has a first length, and
wherein, in the second region, a second width of the third appearance member in the first direction has a second length greater than the first length.

10. A method of driving a deposition apparatus comprising a processor chamber comprising a substrate holder and a transfer chamber configured to transport a substrate on the substrate holder, the method comprising:
placing the substrate on the substrate holder;
forming a vacuum state in an internal space of the processor chamber; and
depositing a deposition material on the substrate while the substrate holder reciprocates,
wherein, in a partial region of the processor chamber, the processor chamber and the transfer chamber overlap with each other.

11. The method of claim 10, wherein the processor chamber further comprises:
a third appearance member defining an internal space therein;
a nozzle portion configured to supply the deposition material to the internal space; and
a first buffer module and a second buffer module coupled to opposite ends of the substrate holder.

12. The method of claim 11, wherein the third appearance member comprises a first region and a second region,
wherein the first region corresponds to the partial region of the processor chamber,
wherein the substrate holder is movable in the second region, and
wherein the first buffer module is movable in the first region and the second region.

13. The method of claim 11, wherein the transfer chamber comprises:
a transport robot configured to allow the substrate to be placed on the substrate holder;
a gate configured to provide a path through which the transport robot is movable to the internal space; and
a gate valve configured to define an open state or a closed state of the gate.

14. The method of claim 13, wherein the gate valve is located on a top of the gate.

15. The method of claim 14, wherein, in the partial region, the processor chamber is located under the transfer chamber.

16. The method of claim 13, wherein the forming of the vacuum state in the internal space comprises allowing, by the gate valve, the gate to be in the closed state.

17. The method of claim 11, wherein the third appearance member comprises a first region, a second region, and a third region, and the second region is located between the first region and the third region,
wherein the partial region corresponds to the first region, and
wherein the third region of the third appearance member is attachable and detachable.

18. The method of claim 11, wherein the third appearance member comprises a first region, a second region, and a third region, and the second region is located between the first region and the third region,
wherein the partial region corresponds to the first region,
wherein, in the first and third regions, a first width of the third appearance member in a first direction has a first length, and
wherein, in the second region, a second width of the third appearance member in the first direction has a second length greater than the first length.

19. The method of claim 18, wherein the depositing of the deposition material on the substrate comprises allowing the nozzle portion to overlap with the first buffer module and arranging the second buffer module on the third region.

20. The method of claim 18, wherein the depositing of the deposition material on the substrate comprises allowing the nozzle portion to overlap with the second buffer module and arranging the first buffer module on the first region.
